(19) United States
(12) Patent Application Publication
(10) Pub. No.: US 2010/0106436 A1
(43) Pub. Date: Apr. 29, 2010

(54) POWER CONSUMPTION CALCULATION FACILITY

(75) Inventors: Hideo Ichinomiya, Kanagawa-ken (JP); Tadashi Tsumura, Kanagawa-ken (JP)

Correspondence Address: IBM CORP. (AUSTIN), C/O NELSON AND NELSON, 2984 E. EVERGREEN AVE., SALT LAKE CITY, UT, 84109, US

(73) Assignee: INTERNATIONAL BUSINESS MACHINES CORPORATION, Armonk, NY (US)

(21) Appl. No.: 12/485,732

(22) Filed: Jun. 16, 2009

(30) Foreign Application Priority Data
Oct. 20, 2008 (JP) 2008-269805

(51) Int. Cl. G01R 21/00; G06F 19/00; G06F 17/30

(52) U.S. Cl. 702/61; 707/E17.044; 707/E17.014

(57) ABSTRACT

Embodiments of the invention include an apparatus for calculating an index value indicating power consumption, processing cost, or environmental load in a system having hardware components used by multiple processes or users. The apparatus may include an index acquisition part for acquiring an index value of a hardware component. The index value may indicate power consumption of the hardware component. The apparatus may further include an observation value acquisition part for acquiring one or more observation values for multiple processes. The observation value for each process may vary depending on use of the hardware component by the process. Finally, a calculation part may calculate, based on the observation value, a use amount of the hardware component by each process. The calculation part may further calculate the index value for a process using the hardware component by distributing the index value according to the use amount.

### RELATED APPLICATIONS

This application claims priority to JP Patent Application No. 2008-269805 filed on Oct. 20, 2008 and entitled CALCULATOR DEVICE, SYSTEM MANAGEMENT APPARATUS, CALCULATION METHOD AND PROGRAM.

### BACKGROUND

Recent developments in data center technology aim to reduce overall power consumption to minimize any chance of disruption in operations.

Power consumption in a data center can be calculated by individually measuring the power consumed by each hardware apparatus, such as a server or communication apparatus. Power consumption for each hardware apparatus may then be totaled to obtain a value indicating overall power consumption for the data center.

A data center often performs various information processes and services in parallel. Individual hardware devices, however, are generally not dedicated to a single process or service and may be shared between multiple data center processes and services.

### SUMMARY

Embodiments of the invention have been developed to facilitate power consumption calculations for a data center having multiple hardware devices.

One embodiment of the invention includes an apparatus for calculating an index value indicating power consumption in a system having a hardware component used by multiple processes or users. The apparatus may include an index acquisition part for acquiring an index value of a hardware component. The index value may indicate power consumption of the hardware component. The apparatus may further include an observation value acquisition part for acquiring one or more observation values for multiple processes. The observation value for each process may vary depending on use of the hardware component by the process. Finally, a calculation part may calculate, based on the observation value, a use amount of the hardware component by each process. The calculation part may further calculate the index value for a process using the hardware component by distributing the index value according to the use amount.

A corresponding system and computer program product are also disclosed and claimed herein.

### BRIEF DESCRIPTION OF THE DRAWINGS

In order that the advantages of the disclosure will be readily understood, a more particular description of embodiments of the invention briefly described above will be rendered by reference to specific embodiments illustrated in the appended drawings. Understanding that these drawings depict only typical embodiments of the invention and are not therefore to be considered limiting of its scope, embodiments of the invention will be described and explained with additional specificity and detail through use of the accompanying drawings, in which:

FIG. 1 shows the configuration of a system management apparatus and data center in accordance with embodiments of the present invention;

FIG. 2 shows one example of data accumulated in an accumulating device in accordance with certain embodiments;

FIG. 3 shows one example of data managed by a configuration management database in accordance with certain embodiments;

FIG. 4 shows a functional configuration of a calculator device in accordance with embodiments of the invention;

FIG. 5 is a flowchart depicting calculator device processing in accordance with certain embodiments;

FIG. 6 is a flowchart detailing the power consumption calculation step of FIG. 5;

FIG. 7 depicts one example of an association history managed by a configuration management database in accordance with certain embodiments of the invention;

FIG. 8 shows configuration of a calculator device in accordance with one embodiment; and

FIG. 9 shows one example of the hardware configuration of a computer in accordance with embodiments of the invention.

### DETAILED DESCRIPTION OF THE INVENTION

It will be readily understood that the components of the embodiments of the invention, as generally described and illustrated in the Figures herein, could be arranged and designed in a wide variety of different configurations. Thus, the following more detailed description of the embodiments of the invention, as represented in the Figures, is not intended to limit the scope of the claims, but is merely representative of certain examples of presently contemplated embodiments in accordance with the invention. The presently described embodiments will be best understood by reference to the drawings, wherein like parts are designated by like numerals throughout.

As will be appreciated by one skilled in the art, embodiments of the invention may be embodied as an apparatus, method, or computer program product. Furthermore, the present invention may take the form of an entirely hardware embodiment, an entirely software embodiment (including firmware, resident software, micro-code, etc.) or an embodiment combining software and hardware elements. Hardware and/or software elements provided to perform various tasks may be generally referred to herein as “modules.” Furthermore, the present invention may take the form of a computer program product embodied in any tangible medium of expression having computer-usable program code embodied in the medium.

Any combination of one or more computer-usable or computer-readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (“RAM”), a read-only memory (“ROM”), an erasable programmable read-only memory (“EPROM” or Flash memory), an optical fiber, a portable compact disc read-only memory (“CDROM”), an optical storage device, transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer-usable program code may be transmitted using any appropriate medium, including but not limited to wireless, wireline, optical fiber cable, RF, etc.

Computer program code for carrying out operations of the present invention may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

The present invention is described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions or code. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

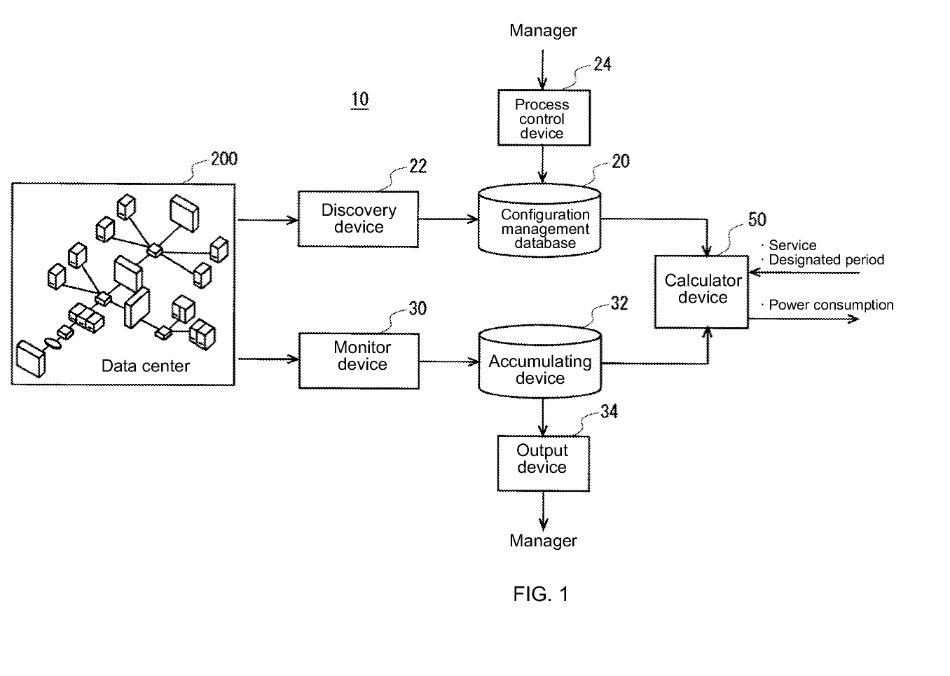

FIG. 1 shows the configuration of a system management apparatus 10 according to an embodiment of the invention, together with a data center 200. The data center 200 may include a plurality of hardware components (also referred to as a “hardware configuration item” or “hardware CI”), such as a plurality of servers or network devices to perform an information process or service. The services performed in the data center 200 may include a process for providing a web page on the Internet, a process for performing a business application such as an accounting process, and a process for performing a series of plural information processes or transactions, for example.

Such a data center 200 may perform a plurality of services in parallel. Each service performed in the data center 200 may utilize one or more data center hardware components, such that the service is performed by operating the hardware component. In some embodiments, each hardware component provided in the data center 200 may be shared by multiple services.

A system management apparatus 10 in accordance with embodiments of the invention may include a configuration management database 20, a discovery device 22, a process control device 24, a monitor device 30, an accumulating device 32, an output device 34 and a calculator device 50. The component database 20 may store an attribute of a component within the data center 200, associations between components, and a history of such associations. A component of the data center 200 may include a hardware CI within the data center 200, middleware operating on the hardware CI, an operation system, an application program and a service, for example.

The discovery device 22 may detect whether the component within the data center 200 and the association between the components are changed. The discovery device 22 may store the attribute of a new component and a change history in the component database 20 if a change is detected.

The process control device 24 may receive an input from the manager, and may manage information stored within the configuration management database 20. The process control device 24 may further control the data center 200 to be configured in accordance with the Information Technology Infrastructure Library (“ITIL”) of the international standards for IT management, for example.

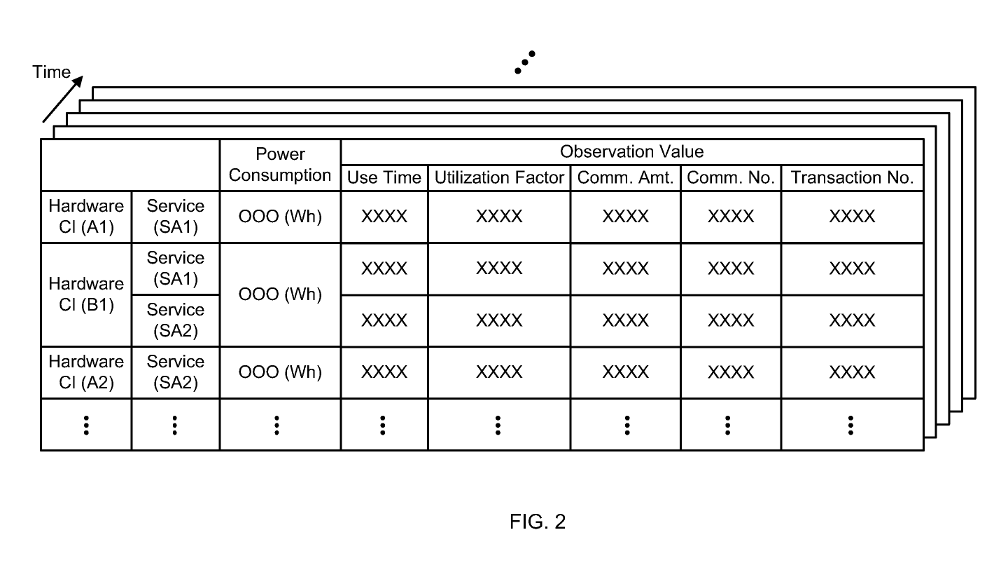

The monitor device 30 may observe the power consumption of each hardware CI within the data center 200. Further, the monitor device 30 may observe, for each of the hardware CIs within the data center 200, one or more observation values that change as a service uses the hardware CI. The observation value will be further described in more detail with reference to FIG. 2 below. The monitor device 30 may observe the power consumption and the observation value for each hardware CI at predetermined time units.

The accumulating device 32 may accumulate the power consumption observed for each hardware CI and the observation value observed for each hardware CI and each service successively. In one embodiment, the accumulating device 32 may be a data warehouse, for example. The output device 34 may output the data accumulated in the accumulating device 32 to the manager.

Any of the services performed in the data center 200 may be designated for the calculator device 50 by the manager or an external program. A period of time used by the calculator device 50 may also be designated by the manager or an external program. The calculator device 50 may calculate the power consumed by the designated data center 200 service within the designated period of time and output the same.

The system management apparatus 10 configured in accordance with embodiments of the invention may manage the data center 200. Further, the system management apparatus 10 may calculate the power consumed by the designated service with reference to the power consumed by the data center 200 as a whole.

In one embodiment, the system management apparatus 10 may calculate the power consumed by the designated service in the data center 200. Alternatively, if the data center 200 is employed in parallel by multiple users, the system management apparatus 10 may calculate the power consumed by a designated user with reference to the total power consumption in the data center 200. Also, the system management apparatus 10 may calculate the power consumption of a system having multiple hardware components in addition to the data center 200.

Referring now to FIG. 2, the accumulating device 32 may accumulate data and may store, for example, the power consumed by each hardware CI in the data center 200, as observed by the monitor device 30, in fixed time period units. In this manner, the accumulating device 32 may provide the power consumed by the designated hardware CI within the designated time period. Also, the accumulating device 32 may store, for each hardware CI provided in the data center 200 and for each service using the hardware CI, at least one observation value, as observed by the monitor device 30, in fixed time period units. The accumulating device 32 may thus provide the observation value of the designated service using the designated hardware CI in the designated time period.

As used herein, the term “observation value” refers to a parameter that is identifiable and observable for each service, and that has a value that changes as the service uses the hardware CI. In some embodiments, the monitor device 30 may observe the use time and the utilization factor of the hardware CI with the service (e.g., the use time and the utilization factor of the CPU of the hardware CI with the service) as the observation value. For example, the monitor device 30 may identify and observe the use time and the utilization factor of the hardware CI for each service by detecting the kind of program or task performed by the hardware CI of object.

In certain embodiments, the monitor device 30 may also observe the communication amount, or the number of communications between the hardware CI and the service, as the observation value. In other embodiments, the monitor device 30 may observe the number of transactions received by the hardware CI according to the use of the service as the observation value. The monitor device 30 may identify and observe the communication amount, the number of communications, or the number of transactions received by the hardware CI for each service by detecting the header information of a packet exchanged by the hardware CI, for example.

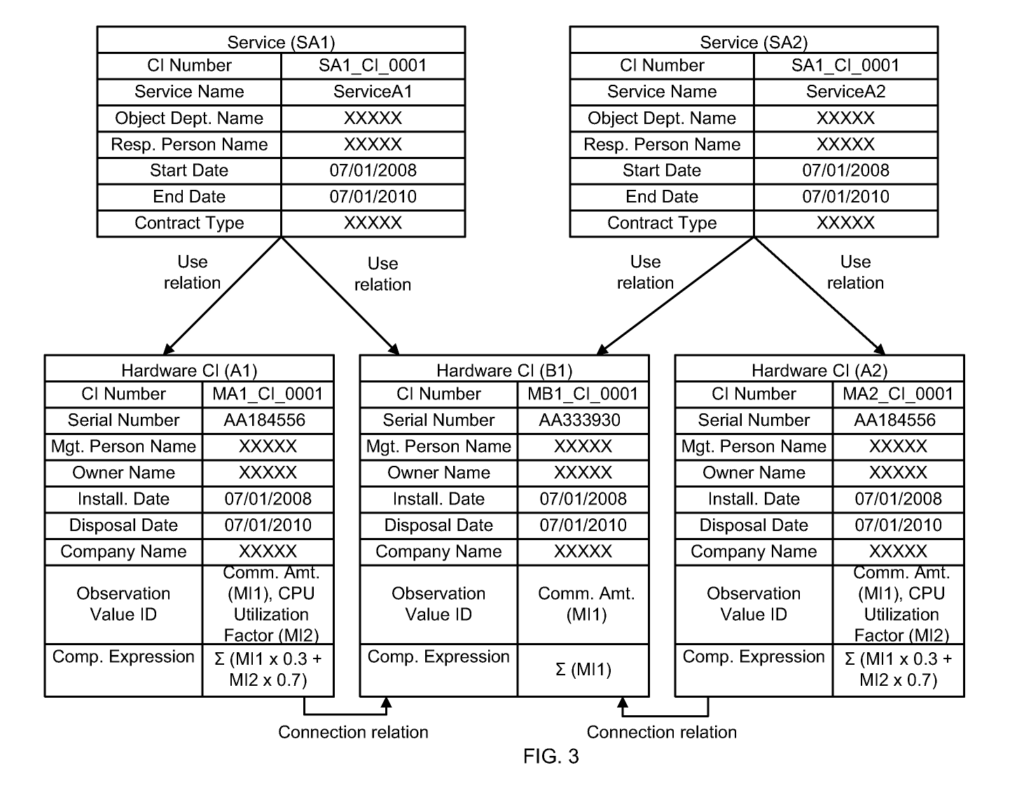

FIG. 3 shows one example of data managed by the configuration management database 20 in accordance with embodiments of the invention. The configuration management database 20 may store, for each component within the data center 200, the attribute of the component. The configuration management database 20 may store, for each component of the service, attributes such as a CI number, a service name, an object department name, a responsible person name, a start date, a scheduled end date, and a contract type, for example. The CI number may be a number intrinsic to each component. In some embodiments, the configuration management database 20 may also store, for each hardware CI, attributes such as a CI number, a serial number, a person name responsible for management, an apparatus owner name, an apparatus installation date, a scheduled disposal date, a manufacturing company name, an observation value identification information and a computation expression.

In some embodiments, the configuration management database 20 may store the computation expression and the observation value identification information for each hardware CI provided in the data center 200. The computation expression may include an expression for obtaining the amount of use of a hardware CI with respect to a service. In this example, the computation expression may obtain a factor representing the amount of power consumed when the service uses the hardware CI.

The computation expression may also include as an input parameter at least one observation value of a service of the hardware CI. For example, as shown in FIG. 3, the computation expression of the hardware CI (A1) may include the communication amount (MI 1) and the utilization factor (MI2) as input parameters. Further, as shown in FIG. 3 for example, the computation expression of the hardware CI (A1) may calculate as the use amount the cumulative value of the communication amount (MI1) of the service multiplied by 0.3 and the CPU utilization factor (MI2) of the service multiplied by 0.7.

In some embodiments, the computation expression may be different according to each hardware CI. The computation expression of each hardware CI may be preset by the manager of the system management apparatus 10 or by the manufacturer of the hardware CI. The computation result (i.e., use amount) may be the value according to a predetermined metric, such as power consumption, of the hardware CI. For example, for an apparatus where the operation power of the CPU is low because the clock cycle is relatively low, and the operation power of the communication device is high because the communication is performed at relatively high speed, the computation expression may be set to add the value of the CPU utilization factor multiplied by a small constant and the value of the communication amount multiplied by a large constant.

The observation value identification information may identify one or more observation values that become the input parameter of the computation expression for the hardware CI. That is, the observation value identification information may identify one or more observation values for use in the computation expression. For example, since the hardware CI (A1) shown in FIG. 3 employs the communication amount (MI1) and the CPU utilization factor (MI2) as input parameters of the computation expression, information identifying the communication amount (MI1) and the CPU utilization factor (MI2) may be described in the observation value identification information.

The configuration management database 20 may store the association between components. In one embodiment, for example, the configuration management database 20 may store, for each service performed in the data center 200, an association representing one or more hardware CIs that may be used with the service (i.e., a usage relationship between the service and the hardware CI).

In certain embodiments, the configuration management database 20 may store, for each hardware CI provided in the data center 200, an association representing other hardware CIs electrically connected with the subject hardware CI (i.e., a connection relationship between hardware CIs). In other embodiments, the configuration management database 20 may store association of the hardware CI with the operation system, and/or association of the operation system with the application program.

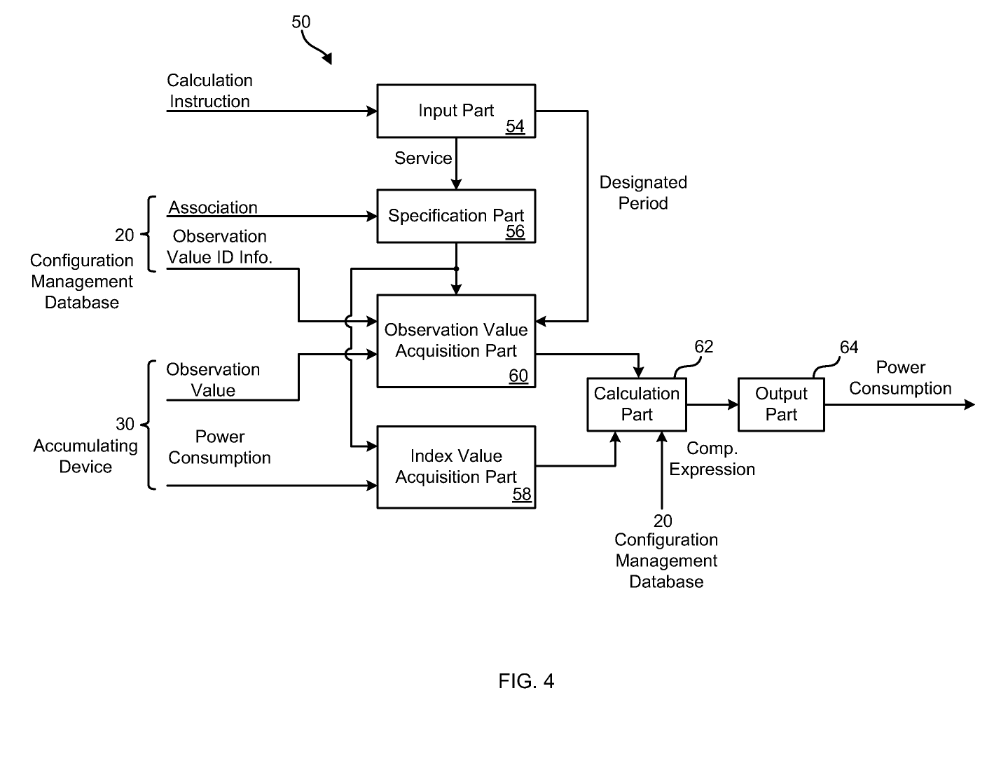

FIG. 4 shows a functional configuration of the calculator device 50 in accordance with certain embodiments of the invention. The calculator device 50 may be realized, for example, by a program running on the computer.

The calculator device 50 may include an input part 54, a specification part 56, an index value acquisition part 58, an observation value acquisition part 60, a calculation part 62 and an output part 64. The input part 54 may accept a calculation instruction from the user or an external program to calculate power consumption for a designated service within a designated time period.

The specification part 56 may obtain access to the configuration management database 20 to specify which hardware CI the designated service may use, since the configuration management database 20 may store an association of each service with each hardware CI. Further, the specification part 56 may gain access to the configuration management database 20 to specify the designated hardware CI that be used by a service performed in the data center 200.

The index value acquisition part 58 may gain access to the accumulating device 32 to acquire the power consumption of each hardware CI specified by the specification part 56. The index value acquisition part 58 may acquire the power consumption within the designated time period, which may be based, for example, on the predetermined time units used by the accumulating device 32 to store the power consumption.

The observation value acquisition part 60 may gain access to the configuration management database 20 to acquire the observation value identification information for each hardware CI specified by the specification part 56. That is, the observation value acquisition part 60 may acquire information identifying one or more observation values for use in the computation expression.

In some embodiments, the observation value acquisition part 60 may gain access to the accumulating device 32 to acquire the observation value identified by the observation value identification information for each service in each hardware CI specified by the specification part 56 by. That is, the observation value acquisition part 60 may acquire, for each service using the hardware CI specified by the specification part 56, one or more observation values for use in the computation expression. The observation value may include, for example, use time, the utilization factor, the communication amount, the number of communications between the hardware CI and the service, and the number of transactions received by the hardware CI. In some embodiments, the index value acquisition part 58 may acquire the observation value in the designated time period from the accumulating device 32. The accumulating device 32 may store the observation value in time series of predetermined time units.

The calculation part 62 may acquire the computation expression for each hardware CI specified by the specification part 56 by gaining access to the configuration management database 20. The calculation part 62 may then calculate the use amount of the hardware CI with each service, based on the observation value of each service using the computation expression and the hardware CI.

The calculation part 62 may further calculate, for each hardware CI specified by the specification part 56, power consumption with the designated service in the hardware CI. This calculation may be derived by distributing the power consumption acquired by the index value acquisition part 58 according to a distribution ratio based on the use amount. The calculation part 62 may then calculate the power consumption with the designated service in the data center 200 by totaling the power consumption with the designated service for each hardware CI specified by the specification part 56. The output part 64 may output to the user or to an external program the power consumption of the designated service in the data center 200, calculated by the calculation part 62.

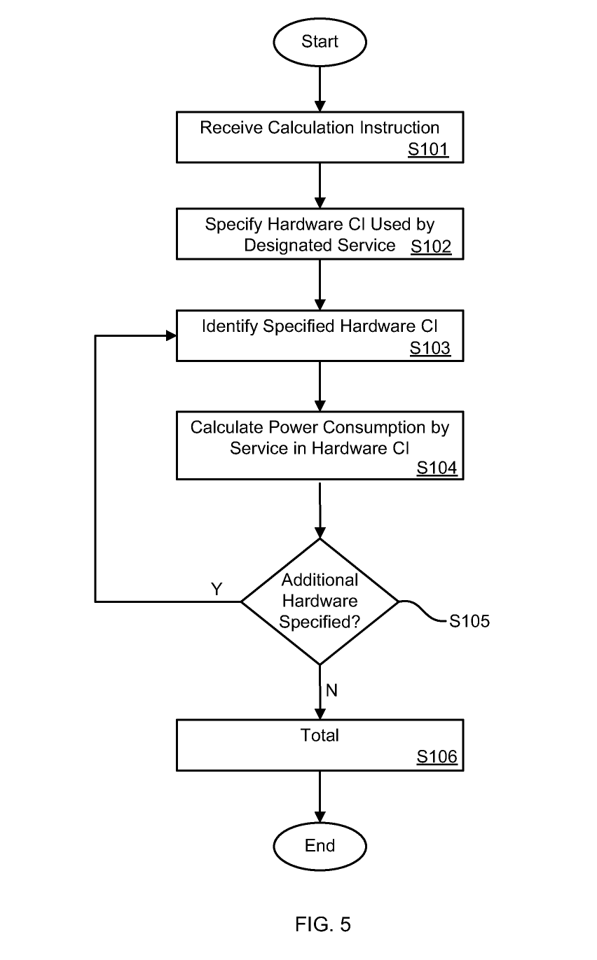

FIG. 5 shows one example of a flow of processing by the calculator device 50 in accordance with certain embodiments of the invention. First, the input part 54 may receive S101, from the user or an external program, a calculation instruction to calculate the power consumed by a designated service within a designated time period.

Subsequently, the specification part 56 may gain access to the configuration management database 20 upon receiving and accepting the calculation instruction in the input part 54. This access may enable the specification part 56 to refer to an association between the designated service and each hardware CI. The specification part 56 may then specify S 102 which hardware CI within the data center 200 the designated service may use.

In some embodiments, the specification part 56 may then process each specified hardware CI to determine power consumption by the designated service in the hardware CI. Specifically, the specification part 56 may identify S103 one hardware CI included in those previously specified. The calculation part 62 may then calculate S104 the power consumed by the designated service for the identified hardware CI.

It may then be determined S105 whether there are additional hardware CIs specified that have not been processed. If it is determined S105 that processing has been completed for all hardware CIs specified, then the calculation part 62 may total S106 the power consumption with the designated service for each of the specified hardware CIs. The output part 64 may then output the total power consumption to the user or the external program.

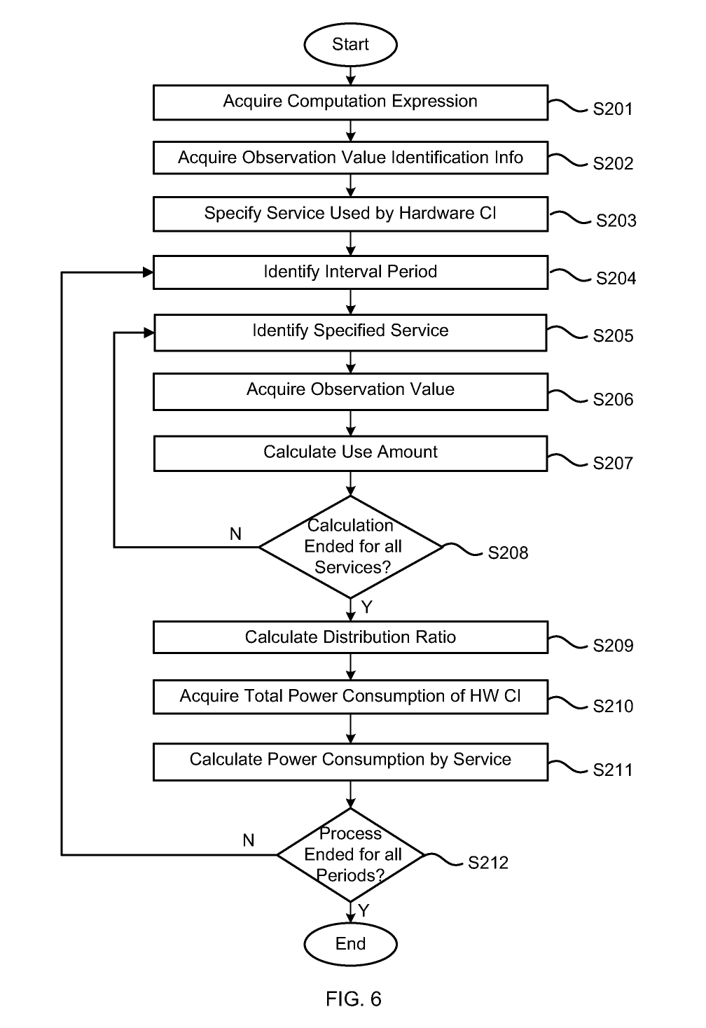

FIG. 6 details the power consumption calculation step S104 of FIG. 5. First, the calculation part 62 may acquire S201 the computation expression for a hardware CI by gaining access to the configuration management database 20 to refer to the attribute of the hardware CI. Subsequently, the observation value acquisition part 60 may acquire S202 the observation value identification information of the hardware CI by gaining access to the configuration management database 20 to refer to the attribute of the hardware CI.

The specification part 56 may then gain access to the configuration management database 20 to refer to the association of the hardware CI with the service to specify S203 by which service the hardware CI may be used. The following processing steps (S204 to S211) may be repeated by the specification part 56 for every interval period included in the designated time period. In some embodiments, the interval period may be the time unit of the power consumption and each observation value stored in time series in the accumulating device 32.

The specification part 56 may cause the observation value acquisition part 60 and the calculation part 62 to perform the processing of the next steps S206 and S207 for each service designated at step S203. In some embodiments, the observation value acquisition part 60 may acquire S206 at least one observation value identified by the observation value identification information and observed in the applicable interval period by gaining access to the accumulating device 32. Subsequently, the calculation part 62 may substitute the acquired observation value into the input parameter of the computation expression. The calculation part 62 may then calculate S207 the use amount of the hardware CI with the service within the interval period.

It may then be determined S208 whether the calculation S207 has been performed for all specified services. If yes, then the calculation part 62 may obtain S209 the distribution ratio for calculating the power consumption of the designated service in the hardware CI from the total power consumption of the hardware CI. More specifically, the calculation part 62 may calculate the distribution ratio as the percentage of use amount of the designated service relative to the total use amount of the specified services.

In some embodiments, the index value acquisition part 58 may gain access to the accumulating device 32 to acquire S210 the total power consumption of the hardware CI observed in the interval period. Subsequently, the calculation part 62 may distribute the total power consumption of the hardware CI in the interval period at the distribution ratio. That is, the calculation part 62 may multiply the total power consumption of the hardware CI in the interval period by the distribution ratio. The calculation part 62 may then calculate S211 the power consumption of the hardware CI by the designated service within the interval period.

It may then be determined S212 whether the process (from step S205 to step S211) has ended for all interval periods. If yes, the specification part 56 may return the operation to step S 104 in FIG. 5. In this case, the calculation part 62 may return the total value of power consumption calculated in every interval period to step S104, or may store the power consumption calculated in every interval period in an array, for example, and return it to step S104.

In some embodiments, the calculation part 62 may use S211 the power consumption acquired by the index value acquisition part 58 as the power consumption of the hardware CI by the designated service, without performing the process from step S205 to step S209 for the hardware CI used exclusively by the specific service. In this case, the calculation part 62 may perform the process from step S205 to step S209 for the hardware CI shared by two or more services, and obtain the power consumption of the hardware CI with the designated service by distributing the power consumption acquired by the index value acquisition part 58 at the distribution ratio according to the use amount at step S211. Also in this case, the specification part 56 may treat the hardware CI associated with the single service as the hardware CI used exclusively by the designated service, and may treat the hardware CI associated with two or more services as the hardware CI shared by two or more services.

In this manner, the system management apparatus 10 may calculate power consumption of the data center 200 for each service. Also, the system management apparatus 10 may calculate power consumption for each service, and may therefore calculate the converted amount of emissions of CO₂ from the calculated power consumption.

In some embodiments, the data center 200 may be shared among multiple users. Accordingly, the system management apparatus 10 may perform each process, which may be performed for each service, for each user. The system management apparatus 10 may thereby calculate power consumption of the data center 200 for each user, in addition to or instead of calculating the power consumption of the data center 200 for each service.

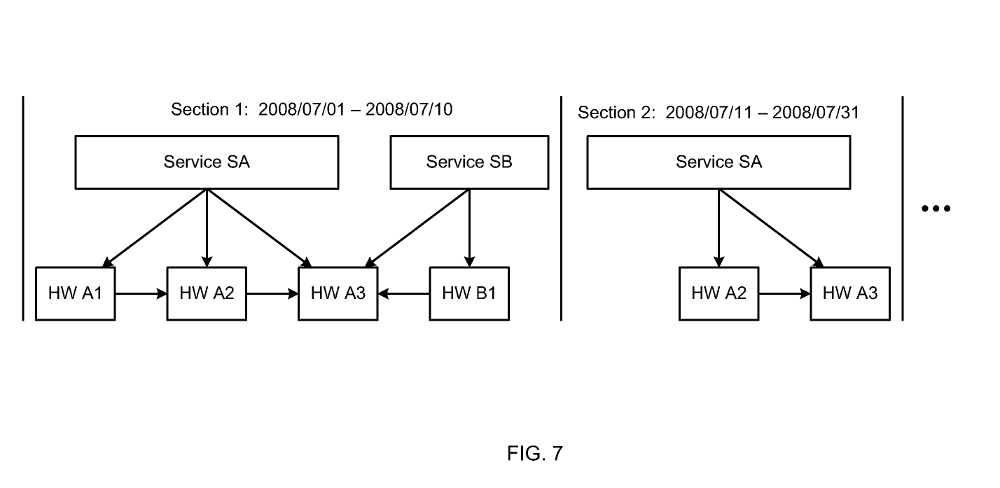

FIG. 7 shows one example of an association history managed by the configuration management database 20 in accordance with embodiments of the invention. The configuration management database 20 may store a history of association between the components. In one embodiment, for example, the configuration management database 20 may store, for each service performed in the data center 200, the association history regarding the one or more hardware CIs used by a particular service, as shown in FIG. 7. Further, in certain embodiments, the configuration management database 20 may include a time indicating a change time of the association in the association history.

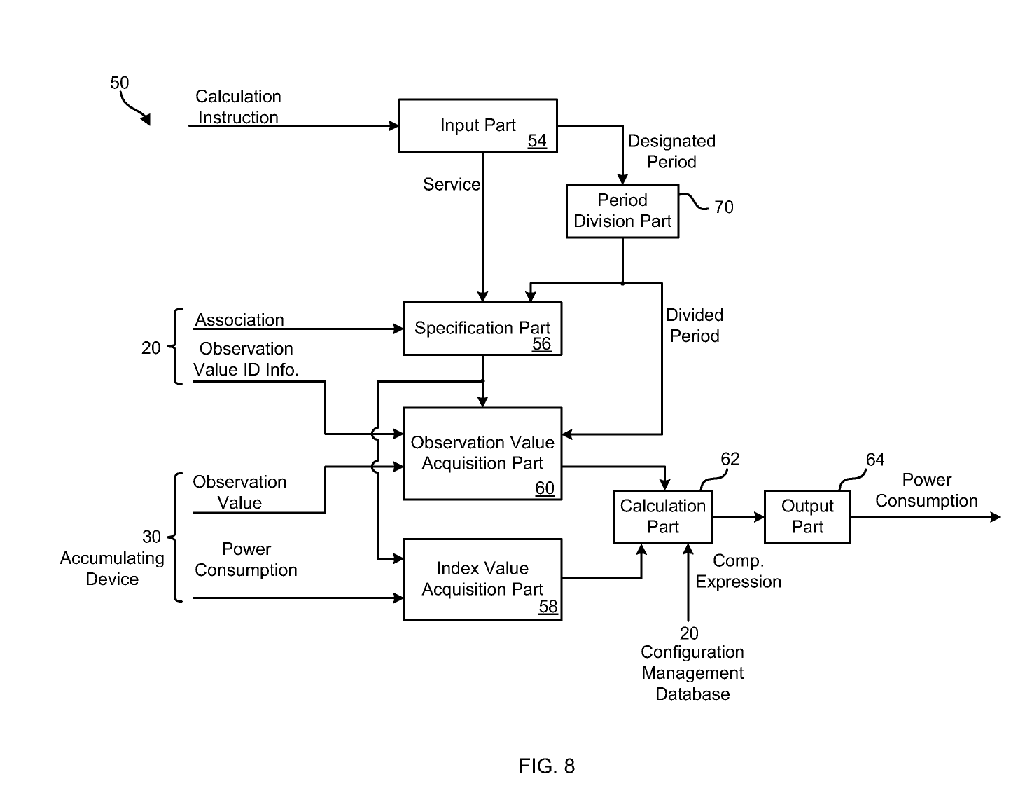

FIG. 8 shows the configuration of a calculator device 50 according to an alternate embodiment. The calculator device 50 according to this embodiment may adopt substantially the same configuration and functions as the calculator device 50 shown in FIG. 4. Accordingly, the same or like parts in the configuration and functions are designated by the same numerals as the parts provided for the calculator device 50 shown in FIG. 4, and the explanation is omitted except for the following distinguishing points.

The calculator device 50 in accordance with this embodiment may further comprise a period division part 70. The period division part 70 may gain access to the configuration management database 20 upon receiving a calculation instruction to calculate power consumption for the designated service in the input designation period. In this manner, the period division part 70 may determine whether or not the association of the hardware CI with the designated service has changed within the designated period. The period division part 70 may allow the calculator device 50 to perform the same processes described with reference to FIG. 4, so long as the association of the hardware CI with the designated service has not changed within the designated period.

The period division part 70 may also divide the designated period into a plurality of divided periods in which the association of the hardware CI with the designated service may be mutually different, if the association of the hardware CI with the designated service has changed within the designated period. In some embodiments, the period division part 70 may allow the calculator device 50 to perform substantially the same processes in each divided period as the process performed for the designated period.

That is, in this case, the specification part 56 may specify which hardware CI (of the plurality of hardware CIs) the designated service may use in each divided period. Further, the specification part 56 may specify by which service each of the specified hardware CIs may be used.

The index value acquisition part 58 may acquire the power consumption of each of the specified hardware CIs in each divided period. Also, the observation value acquisition part 60 may acquire, for each specified service in each of the specified hardware CIs in each divided period, at least one observation value that may change depending on the use of the hardware CI with the particular service. Also, the calculation part 62 may calculate the power consumption of each of the specified hardware CIs with the designated service in each divided period, and may calculate the power consumption with the designated service in the data center 200 by totaling the calculated power consumption.

The calculation part 62 may calculate the power consumption with the designated service in the designated period by totaling the power consumption calculated in each divided period. The power consumption of the data center 200 may thus be calculated for each service, even in the period where the component in the data center 200 is changed.

Though the present invention has been described above with reference to certain embodiments, those skilled in the art will appreciate that various changes or improvements may be made to the above embodiments. It will also be apparent from the claims that such changes, improvements, and alternate embodiments may be included within the technical range of the invention.

For example, in some embodiments, the calculator device 50 may calculate the index value indicating a processing cost or environmental load by the process or the user in the data center 200, instead of calculating the power consumption in the data center 200. The processing cost may be an expenditure, such as personal expenditure or energy spent in the operation and maintenance of the data center 200, for example. An environmental load may indicate emissions of CO₂ and a quantity of heat discharged by operation of the data center 200, for example.

In such a case, the index value acquisition part 58 may acquire the index value indicating the processing cost or environmental load from the database managing the index value for each hardware component. The calculation part 62 may make the distribution for the index value at the ratio calculated using the computation expression. In certain embodiments, the calculator device 50 may calculate the index value indicating the processing cost or environmental load in the data center 200 for each process or user.

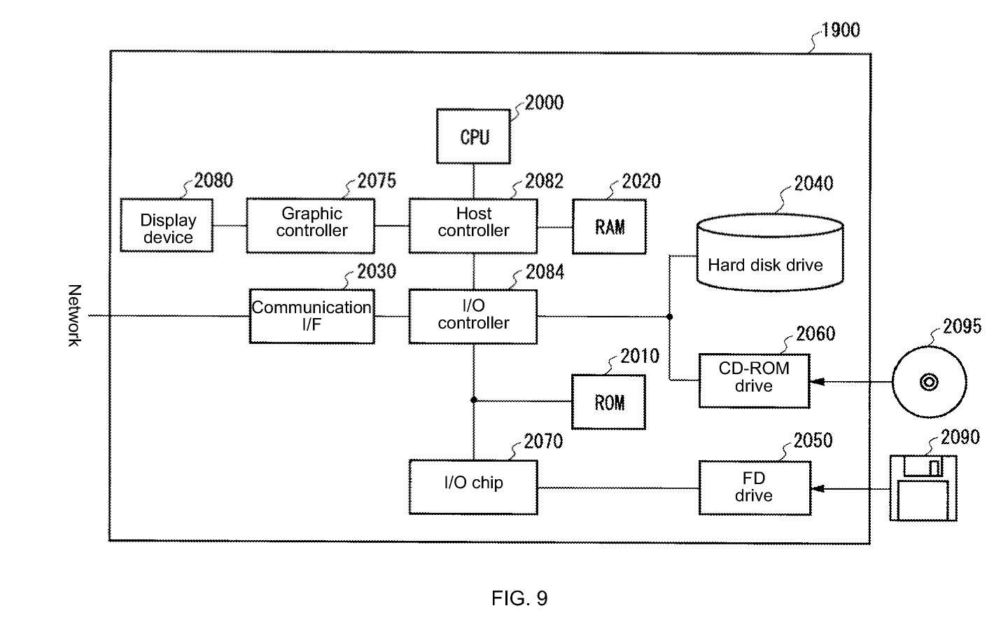

FIG. 9 shows one example of a hardware configuration of a computer 1900 in accordance with one embodiment of the invention. The computer 1900 may include a CPU peripheral part having a CPU 2000, a RAM 2020, a graphic controller 2075 and a display device 2080 that are interconnected by a host controller 2082, an input/output part having a communication interface 2030, a hard disk drive 2040, and a CD-ROM drive 2060. These parts may also be connected to the host controller 2082 by an input/output controller 2084, and a legacy input/output part having a ROM 2010, a flexible disk drive 2050 and an input/output chip 2070 that are connected to the input/output controller 2084.

The host controller 2082 may connect the RAM 2020 with the CPU 2000 and the graphic controller 2075. The CPU 2000 may access the RAM 2020 at a high transfer rate. Further, the CPU 2000 may operate based on a program stored in the ROM 2010 and the RAM 2020 and may control each component. The graphic controller 2075 may acquire the image data generated on a frame buffer that the CPU 2000 provides within the RAM 2020, and may display it on the display device 2080. Alternatively, the graphic controller 2075 may comprise internally the frame buffer for storing the image data generated by the CPU 2000.

The input/output controller 2084 may connect the host controller 2082 with relatively fast input/output devices such as the communication interface 2030, the hard disk drive 2040, and the CD-ROM drive 2060. The communication interface 2030 may communicate with other apparatuses via a network. The hard disk drive 2040 may store the program and data used by the CPU 2000 within the computer 1900. The CD-ROM drive 2060 may read the program or data from the CD-ROM 2095 and provide it via the RAM 2020 to the hard disk drive 2040.

The input/output controller 2084 may also be connected to input/output devices having relatively low speed such as the ROM 2010, the flexible disk drive 2050, and the input/output chip 2070. The ROM 2010 may store a boot program executed when the computer 1900 is started, as well as programs dependent on the hardware of the computer 1900. The flexible disk drive 2050 may read the program or data from the flexible disk 2090 and provide it via the RAM 2020 to the hard disk drive 2040. The input/output chip 2070 may connect the flexible disk drive 2050 to the input/output controller 2084, and may connect various kinds of input/output devices to the input/output controller 2084 via a parallel port, a serial port, a keyboard port, a mouse port, or the like.

The program provided via the RAM 2020 to the hard disk drive 2040 may be provided by the user and stored in a recording medium such as the flexible disk 2090, the CD-ROM 2095 or an IC card. The program may be read from the recording medium, installed in the hard disk drive 2040 within the computer 1900 via the RAM 2020, and executed on the CPU 2000.

A program that may be installed in the computer 1900 for enabling the computer to function as the calculator device 50 may include an input module, a specification module, an index value acquisition module, an observation value acquisition module, a calculation module, and an output module. These programs or modules may operate on the CPU 2000 to enable the computer 1900 to function as the input part 54, the specification part 56, the index value acquisition part 58, the observation value acquisition part 60, the calculation part 62 and the output part 64, respectively.

An information process described in these programs may be read into the computer 1900 and may function as the input part 54, the specification part 56, the index value acquisition part 58, the observation value acquisition part 60, the calculation part 62 and the output part 64. These parts may provide specific means by which the software and various kinds of hardware resources may cooperate. Further, in some embodiments, these parts may be included in the calculator device 50, whereby operation or processing of the information may be performed according to the purpose or use of the computer 1900.

For example, when the computer 1900 communicates with an external apparatus, the CPU 2000 may execute a communication program loaded into the RAM 2020, and may instruct the communication interface 2030 to perform a communication process based on the processing contents described in the communication program. The communication interface 2030 may read the send data stored in a transmission buffer area provided in the storage device such as the RAM 2020, the hard disk drive 2040, the flexible disk 2090 or the CD-ROM 2095. The communication interface 2030 may then send it to the network, or may write the data received from the network into a reception buffer area provided in a storage device under the control of the CPU 2000. In this manner, the communication interface 2030 may transfer the data to or from the storage device by a Direct Memory Access (“DMA”) method. Alternatively, the CPU 2000 may read the data from the storage device or the communication interface 2030 of a transfer source, and may write it into the communication interface 2030 or the storage device of a transfer destination.

In some embodiments, as part of the DMA transfer, the CPU 2000 may read all or part of a file or database stored in an external storage device such as the hard disk drive 2040, the CD-ROM drive 2060 (CD-ROM 2095) or the flexible disk drive 2050 (flexible disk 2090) into the RAM 2020. The CPU 200 may perform various types of processing on the data in the RAM 2020. After such processing, the CPU 2000 may write back the data into the external storage device by DMA transfer. During such a process, the RAM 2020 may temporarily hold the contents of the external storage device, such that the RAM 2020 and the external storage device may be generally regarded as a memory, storage part or storage device.

Further, in this embodiment, various kinds of information such as a program, data, table and database may be stored in such a storage device, and may be subject to such information processing. In certain embodiments, the CPU 2000 may hold a part of the RAM 2020 in a cache memory, and may read or write the data on the cache memory. In such an embodiment, since the cache memory may bear a part of the function of the RAM 2020, the cache memory may also be included in the RAM 2020, memory and/or storage device.

In some embodiments, the CPU 2000 may perform various types of processing, including various kinds of arithmetic operations, processing of information, conditional judgments, and search or replacement of information specified in an instruction code of the program. For example, the CPU 2000 may determine whether or not a condition is satisfied, where the condition specifies that certain variables are greater than, less than, greater than or equal to, less than or equal to, or equal to other variables or constants. The process may branch to a different instruction code or may call a subroutine depending on whether the condition is satisfied.

In certain embodiments, the CPU 2000 may search for information stored in the file or database within the storage device. For example, where multiple entries are stored having an attribute value of the first attribute associated with an attribute value of the second attribute in the storage device, the CPU 2000 may search for an entry in which the attribute value of the first attribute matches the designated condition. The CPU 2000 may then read the attribute value of the second attribute stored in the entry to obtain the attribute value of the second attribute associated with the first attribute in which the predetermined condition is satisfied.

In some embodiments, the program or module presented above may be stored in an external recording medium. Examples of the recording medium may include the flexible disk 2090, the CD-ROM 2095, an optical recording medium, such as DVD or CD, a magneto-optical recording medium such as a magneto-optical (“MO”) disk, a tape medium, or a semiconductor memory such as IC card. In some embodiments, the program may be provided via the network to the computer 1900 using the storage device (such as the hard disk or RAM provided in a server system) connected to the dedicated communication network or the Internet as the recording medium.

One skilled in the art will recognize, of course, that an execution sequence included in any process herein, such as an operation, procedure, step or stage in an apparatus, system, program or method in accordance with embodiments of the invention, may not be clearly expressed as “before” or “ahead” of any other operation, procedure, step or stage, and may be implemented in any sequence, unless the output of the previous process is used in the succeeding process. While a flow of operation may be described for convenience herein using “first,” “next,” and so on, such operation does not necessarily need be performed in this sequence.

1. An apparatus for calculating an index value indicating power consumption in a system having a hardware component used by a plurality of processes, the apparatus comprising:
an index value acquisition part for acquiring an index value of a hardware component, wherein the index value indicates power consumption of the hardware component;
an observation value acquisition part for acquiring, for each of a plurality of processes, at least one observation value, the observation value changing depending on use of the hardware component by the process; and
a calculation part for calculating, based on the observation value, a use amount of the hardware component by each of the plurality of processes, and for calculating the index value for a process using the hardware component by distributing the index value according to the use amount.

2. The apparatus of claim 1, wherein the calculation part gains access to a configuration management database to acquire a computation expression, wherein the computation expression uses the observation value to provide the use amount of the hardware component by a process.

3. The apparatus of claim 2, wherein the calculation part further calculates the use amount of the hardware component by each of the plurality of processes using the computation expression and the observation value for each of the plurality of processes and calculates the index value for the process by distributing the index value according to a distribution ratio based on the use amount.

4. The apparatus of claim 3, wherein the configuration management database stores observation value identification information identifying the observation value, and wherein the observation value acquisition part gains access to the configuration management database to acquire the observation value identification information.

5. The apparatus of claim 4,wherein the observation value acquisition part further acquires in the hardware component the observation value identified by the observation value identification information.

6. The apparatus of claim 1, wherein the observation value acquisition part acquires as the observation value at least one of a use time, a utilization factor, a communication amount, a number of communications between the hardware component and the process, and a number of transactions received by the hardware component.

7. The apparatus of claim 1, further comprising a specification part for specifying which of a plurality of hardware components the process uses.

8. The apparatus of claim 7, wherein the calculation part identifies the index value as one of used exclusively by the process in the hardware component, and shared by at least two processes in the hardware component.

9. The apparatus of claim 8, wherein the calculation part distributes the index value according to the distribution ratio based on the use amount by the process in the hardware component where the hardware component is shared by two or more processes, and wherein the calculation part calculates the index value for the process by totaling the index values for each of the plurality of the hardware components used by the process.

10. The apparatus of claim 8, wherein the specification part gains access to a configuration management database associating each of the hardware components with each process to determine whether the hardware component is one of associated with a single process, and associated with at least two processes.

11. The apparatus of claim 10, wherein the configuration management database stores an association history of each hardware component with each process, and further comprising a period division part for dividing a time period into a plurality of divided time periods in which association of the hardware component with the process is mutually different.

12. The apparatus of claim 11, wherein association of the hardware component with the process within the time period has been changed upon the calculation part receiving a calculation instruction to calculate the index value for the process in the time period.

13. The apparatus of claim 12, wherein the specification part specifies which hardware component of the plurality of hardware components the process uses in each of the divided time periods, and wherein the calculation part calculates the index value for the process in each of the divided time periods.

14. A system for managing at least one hardware component used by a plurality of processes, the system comprising:
a component database storing a computation expression for obtaining a use amount of a hardware component by a process, the computation expression using at least one observation value associated with the hardware component; and
a calculator device for calculating an index value indicating power consumption of at least one hardware component used by a plurality of processes, the calculator device comprising:
an index value acquisition part for acquiring an index value of a hardware component, wherein the index value indicates power consumption of the hardware component;
an observation value acquisition part for acquiring, for each of a plurality of processes, at least one observation value, the observation value changing depending on use of the hardware component by the process; and
a calculation part for calculating the use amount of the hardware component by each of the plurality of processes, and for calculating the index value for the process using the hardware component by distributing the index value according to the use amount, wherein the calculation part gains access to the component database to calculate the use amount using the computation expression and the observation value for each of the plurality of processes.

15. The system of claim 14, wherein the index value indicates at least one of power consumption, processing cost, and environmental load.

16. A computer program product for calculating an index value indicating power consumption in a system having a hardware component used by a plurality of processes, the computer program product comprising:
a computer-usable medium having a computer-usable program code embodied therein, the computer-usable program code comprising:
computer-usable program code for acquiring an index value for a hardware component, wherein the index value indicates power consumption of the hardware component;
computer-usable program code for acquiring, for each of a plurality of processes, at least one observation value, the observation value changing depending on use of the hardware component by the process; and
computer-usable program code for calculating, based on the observation value, the use amount of the hardware component by each of the plurality of processes, and for calculating the index value for a process using the hardware component by distributing the index value according to the use amount.

17. The computer program product of claim 16, wherein the index value indicates at least one of power consumption, processing cost, and environmental load.
